(19) United States
(12) Patent Application Publication
(10) Pub. No.: US 2011/0156203 A1
(43) Pub. Date: Jun. 30, 2011

(54) INTEGRATED PASSIVE DEVICE ASSEMBLY

(75) Inventors: Sang Wook PARK, Gyunggi-do (KR); Chul Hwan YOON, Gyunggi-do (KR); Youn Suk KIM, Gyunggi-do (KR); Seong Geun KIM, Gyunggi-do (KR); Sang Hee KIM, Seoul (KR); Jae Hyouck CHOI, Gyunggi-do (KR); Jun Kyung NA, Gyunggi-do (KR)

(73) Assignee: SAMSUNG ELECTRO-MECHANICS CO., LTD., Gyunggi-do (KR)

(21) Appl. No.: 12/823,678

(22) Filed: Jun. 25, 2010

(30) Foreign Application Priority Data
Dec. 29, 2009 (KR) 10-2009-0133439

(51) Int. Cl. H01L 29/86

(52) U.S. Cl. 257/528; 257/E29.325

(57) ABSTRACT

There is provided an integrated passive device assembly. An integrated passive device assembly according to an aspect of the invention may include: a board having a wiring pattern provided thereon; an integrated passive device mounted on an upper surface of the board and having conductive patterns provided on upper and lower surfaces thereof; a first connection portion electrically connecting the conductive pattern, provided on the upper surface of the integrated passive device, and the wiring pattern to each other; and a second connection portion electrically connecting the conductive pattern, provided on the lower surface of the integrated passive device, and the wiring pattern to each other.

### CROSS-REFERENCE TO RELATED APPLICATIONS

This application claims the priority of Korean Patent Application No. 10-2009-0133439 filed on Dec. 29, 2009, in the Korean Intellectual Property Office, the disclosure of which is incorporated herein by reference.

### BACKGROUND OF THE INVENTION

1. Field of the Invention

The present invention relates to integrated passive device assemblies, and more particularly, to an integrated passive device assembly that increases space utilization and has improved reliability.

2. Description of the Related Art

An integrated passive device (IPD) is manufactured by integrating passive circuit components, such as resistors, inductors, and capacitors, included in photoelectric integrated circuit systems or wireless communications components, into a small semiconductor substrate.

In a system using high-frequency electronic components, individual passive devices, which are difficult to integrate due to technical limitations, can be integrated using IPD technology, thereby preventing an increase in circuit size and increasing high-frequency characteristics.

However, in general, a conductive pattern is formed on one surface of an integrated passive device, while the other surface of the integrated passive device is mounted on a wiring board using an adhesive. For this reason, general integrated passive devices are disadvantageous with respect to space utilization.

With the recent demand for a size reduction and miniaturization of electronic products, there has been a need to reduce the size of integrated passive devices. Therefore, there is a need for integrated passive devices capable of realizing a wider array of passive devices within the same space or realizing a passive device having a larger capacity.

### SUMMARY OF THE INVENTION

An aspect of the present invention provides an integrated passive device assembly capable of realizing a larger number of passive devices within the same space.

An aspect of the present invention also provides an integrated passive device assembly capable of realizing a passive device having a larger capacity within the same space.

According to an aspect of the present invention, there is provided an integrated passive device assembly including: a board having a wiring pattern provided thereon; an integrated passive device mounted on an upper surface of the board and having conductive patterns provided on upper and lower surfaces thereof: a first connection portion electrically connecting the conductive pattern, provided on the upper surface of the integrated passive device, and the wiring pattern to each other; and a second connection portion electrically connecting the conductive pattern, provided on the lower surface of the integrated passive device, and the wiring pattern to each other.

The first connection portion may be a wire electrically connecting the conductive pattern, provided on the top surface of the integrated passive device, and the wiring pattern to each other, and the second connection portion may be a conductive bump electrically connecting the conductive pattern, provided on the lower surface of the integrated passive device, and the wiring pattern to each other.

The wire and the conductive bump may be electrically connected to each other through the wiring pattern.

The integrated passive device may include a passivation layer formed of an insulating material in order to protect the conductive pattern, provided on the lower surface thereof.

The first connection portion may be a wire electrically connecting the conductive pattern, provided on the upper surface of the integrated passive device, and the wiring pattern to each other, and the second connection portion may be a via electrically connecting the conductive pattern, provided on the lower surface of the integrated passive device, and the conductive pattern on the upper surface thereof.

The integrated device may be mounted on the board by attaching the passivation layer, provided on a bottom surface of the integrated passive device, to the board through an adhesive.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating an integrated passive device assembly according to an exemplary embodiment of the present invention; and

FIG. 2 is a cross-sectional view illustrating an integrated passive device assembly according to another exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art.

It is considered that parts having the same configuration and functions have substantially the same reference numerals in the accompanying drawings of the present invention.

In the entire specification, it should be noted that when a portion “is connected to” other portions, the portion can be directly connected to the other portions or indirectly connected to the other portions with intervening any of elements present. In addition, it should be noted that a phrase that a portion “includes” an element(s) means that the portion does not exclude but include the other elements unless otherwise stated herein.

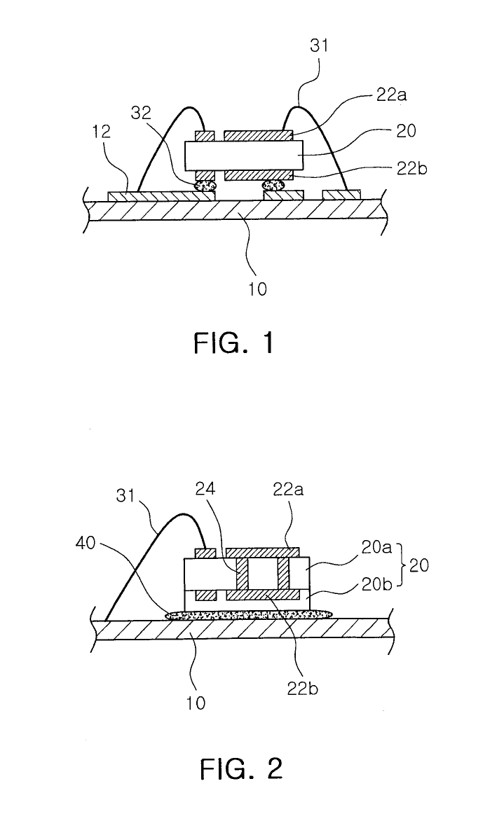

FIG. 1 is a cross-sectional view illustrating an integrated passive device assembly according to an exemplary embodiment of the invention.

Referring to FIG. 1, an integrated passive device assembly according to this embodiment may include a board 10, an integrated passive device 20, wires 31, and conductive bumps 32.

The board 10 may be a printed circuit board having wiring patterns formed on an upper surface thereof on the top and within the inside thereof. In FIG. 1, the board 10, having wiring patterns 12 formed on the upper surface thereof, is illustrated.

Though not shown in FIG. 1, a plurality of circuit devices as well as the integrated passive device 20 may be mounted on the board 10. Here, the integrated passive device 20 and other circuit devices, being mounted on the board 10, may be electrically connected to each other through the wiring patterns 12 formed on the upper surface of the board 10.

Furthermore, the integrated passive device 20 and other circuit devices, being mounted on the board 10, may be provided with external power through the wiring patterns 12.

The integrated passive device 20 may be manufactured by forming conductive patterns 22a and 22b on the upper and lower surfaces of a semiconductor substrate, respectively in order to realize a passive device, such as a resistor, an inductor, or a capacitor.

Here, the conductive patterns 22a and 22b, formed on the upper and lower surfaces of the integrated passive device 20, may be formed in order to realize the same passive device or passive devices different from each other.

For example, the conductive pattern 22a on the upper surface of the integrated passive device 20 may be formed to realize a resistor, while the conductive pattern 22b on the bottom surface thereof may be formed to realize an inductor. Here, both the resistor and the inductor can be realized in a space within which one integrated passive device is mounted, thereby increasing space utilization and thus allowing greater miniaturization of the entire electronic product.

Alternatively, the conductive pattern 22a and the conductive pattern 22b, formed on the upper and lower surfaces of the integrated passive device 20, respectively, may be formed in order to realize a single inductor. Here, the conductive pattern 22a and the conductive pattern 22b, formed on the upper and lower surfaces of the integrated passive device 20, respectively, are electrically connected through the wiring patterns 12, the wires 31, and the conductive bumps 32, so that the conductive patterns 22a and 22b, electrically connected to each other, can serve as one passive device. Therefore, it is possible to realize an inductor having a larger capacity within the same space, thereby increasing space utilization and allowing greater miniaturization of the entire electronic product.

The wires 31 may electrically connect the conductive pattern 22a, formed on the upper surface of the integrated passive device 20, and the wiring patterns 12 provided on the board 10.

The conductive bumps 32 may electrically connect the conductive pattern 22b, formed on the lower surface of the integrated passive device 20, and the wiring patterns 12 provided on the board 10.

FIG. 2 is a cross-sectional view illustrating an integrated passive device assembly according to another exemplary embodiment of the invention.

Referring to FIG. 2, an integrated passive device assembly according to this embodiment may include the board 10, the integrated passive device 20, and the wire 31.

Though not shown in FIG. 2, the board 10 may be a printed circuit board having wire patterns formed on an upper surface thereof on the top and within the inside thereof.

The integrated passive device 20 may be manufactured by forming the conductive patterns 22a and 22b on the upper and lower surfaces of a semiconductor substrate, respectively, in order to realize a passive device, such as a resistor, an inductor, or a capacitor.

Furthermore, the integrated passive device 20 may include vias 24 that electrically connect the conductive pattern 22a, formed on the upper surface of the integrated passive device 20, and the conductive pattern 22b, formed on the lower surface thereof.

The integrated passive device 20 may include a passivation layer 20b that is formed of an insulating material in order to protect the conductive pattern 22b formed on the lower surface thereof.

The conductive pattern 22b, formed on the lower surface of the integrated passive device 20, is connected to the conductive pattern 22a, formed on the upper surface thereof, through the vias 24, and is not electrically connected to wring patterns on the board 10. Therefore, the conductive pattern 22a and the conductive pattern 22b, formed on the upper and lower surfaces of the integrated passive device 20, respectively, may be formed to realize the same passive device.

For example, both the conductive pattern 22a and the conductive pattern 22b, formed on the upper and lower surfaces of the integrated passive device 20, respectively, may be formed to realize a single inductor. Here, the conductive pattern 22a and the conductive pattern 22b, formed on the upper and lower surfaces thereof, respectively, are electrically connected to each other through the vias 24, so that an inductor having a larger capacitor can be realized within the same space. Therefore, space utilization is increased, and the miniaturization of the entire electronic product is thereby facilitated.

The integrated passive device 20 may be mounted on the board 10 in such a manner that the passivation layer 20b is attached to the board 10 through an adhesive.

The wire 31 may electrically connect the conductive pattern 22a, formed on the upper surface of the integrated passive device 20, and the wiring patterns (not shown) of the board 10.

The conductive pattern 22a, formed on the upper surface of the integrated passive device 20, is connected to the wiring patterns (not shown) of the board 10 through the wire 31, and the conductive pattern 22b, formed on the lower surface thereof, is connected to the conductive pattern 22a, formed on the upper surface thereof, through the vias 24, so that the conductive pattern 22b, formed on the lower surface thereof, may be electrically connected to the wiring patterns (not shown) of the board 10.

As set forth above, according to exemplary embodiments of the invention, in an integrated passive device assembly, conductive patterns are formed on both surfaces of a device in order to realize different passive devices, thereby realizing a wider array of passive devices within the same space.

Furthermore, conductive patterns are formed on both surfaces of a device in order to realize one passive device, thereby realizing a passive device having a larger capacity within the same space.

While the present invention has been shown and described in connection with the exemplary embodiments, it will be apparent to those skilled in the art that modifications and variations can be made without departing from the spirit and scope of the invention as defined by the appended claims.

What is claimed is:

1. An integrated passive device assembly comprising:
a board having a wiring pattern provided thereon;
an integrated passive device mounted on an upper surface of the board and having conductive patterns provided on upper and lower surfaces thereof;
a first connection portion electrically connecting the conductive pattern, provided on the upper surface of the integrated passive device, and the wiring pattern to each other; and
a second connection portion electrically connecting the conductive pattern, provided on the lower surface of the integrated passive device, and the wiring pattern to each other.

2. The integrated passive device assembly of claim 1, wherein the first connection portion is a wire electrically connecting the conductive pattern, provided on the top surface of the integrated passive device, and the wiring pattern to each other, and
the second connection portion is a conductive bump electrically connecting the conductive pattern, provided on the lower surface of the integrated passive device, and the wiring pattern to each other.

3. The integrated passive device assembly of claim 2, wherein the wire and the conductive bump are electrically connected to each other through the wiring pattern.

4. The integrated passive device assembly of claim 1, wherein the integrated passive device comprises a passivation layer formed of an insulating material in order to protect the conductive pattern, provided on the lower surface thereof.

5. The integrated passive device assembly of claim 4, wherein the first connection portion is a wire electrically connecting the conductive pattern, provided on the upper surface of the integrated passive device, and the wiring pattern to each other, and
the second connection portion is a via electrically connecting the conductive pattern, provided on the lower surface of the integrated passive device, and the conductive pattern on the upper surface thereof.

6. The integrated passive device assembly of claim 4, wherein the integrated passive device is mounted on the board by attaching the passivation layer, provided on a bottom surface of the integrated passive device, to the board through an adhesive.
